(19) United States
(12) Patent Application Publication
(10) Pub. No.: US 2019/0354222 A1
(43) Pub. Date: Nov. 21, 2019

(54) TRIBOELECTRIC SENSOR WITH HAPTIC FEEDBACK

(71) Applicant: SABIC GLOBAL TECHNOLOGIES B.V., Bergen op Zoom (NL)

(72) Inventors: Jesus Alfonso Caraveo FRESCAS, Thuwal (SA); Ramzi Salem AL-MAGHATHUWI, Thuwal (SA); Abdulaziz H. ALDUBAYAN, Thuwal (SA); Pradipta K. NAYAK, Thuwal (SA)

(73) Assignee: SABIC Global Technologies B.V., Bergen op Zoom (NL)

(21) Appl. No.: 16/476,236

(22) PCT Filed: Jan. 5, 2018
(86) PCT No.: PCT/IB2018/050081

§ 371 Date: Jul. 5, 2019

Related U.S. Application Data
(60) Provisional application No. 62/443,193, filed on Jan. 6, 2017.

(51) Int. Cl. G06F 3/041; G06F 3/023; G06F 3/01; H03K 17/96

(52) U.S. Cl. CPC G06F 3/0414; G06F 3/0231; H03K 2217/94089; H03K 17/9618; G06F 3/016

(57) ABSTRACT

Triboelectric-based sensors used to receive touch-based input from a user and control electronic devices are described. A triboelectric-based sensors may also incorporate a haptic feedback device, such as an actuator, co-located on the same substrate as the triboelectric-based sensor. The haptic feedback device and the triboelectric-based sensor may share an active polymer layer. The triboelectric-based sensors may include an active layer made from a perfluoronated copolymer, such as poly(methyl methacrylate)-co-poly(1H,1H-perfluoroctyl methacrylate) manufactured by free radical polymerization in benzene.

### CROSS-REFERENCE TO RELATED APPLICATIONS

This application claims the benefit of priority of U.S. Provisional Patent Application No. 62/443,193 filed Jan. 6, 2017, which is hereby incorporated by reference in its entirety.

### FIELD OF THE DISCLOSURE

The instant disclosure relates to user input devices. More specifically, this disclosure relates to user input devices based on triboelectric sensors.

### BACKGROUND

Interaction with electronic devices, such as computers, home appliances, or car consoles, has been characterized by the use of mechanical switches (keyboard, buttons, knobs, etc.) as the input mechanism for the given system to perform an action. An on/off switch in many appliances is a mechanical switch that lets current flow through it when pressed, but presents a large resistance to current flow when not pressed. Switches are used in computer keyboards, which users apply force to enter the desired letter. Some recent developments incorporate the use of touch sensitive technology to replace the mechanical switches. Capacitive, resistive, or optical-based proximity, or touch sensors are being used to replace mechanical switches and knobs, such as those found in a car's console. Touch-sensitive displays are embedded into systems like mobile phones, tablets, or even ATM machines. However, the conventional touch-sensitive technologies have a major drawback in that there is a lack of sense of touch for the user. That is, a user cannot feel operation of the device like a mechanical switch.

Examples of conventional touch sensors are shown in FIG. 1A and FIG. 1B. FIG. 1A is an illustration of a mechanical switch according to the prior art. A wall switch 102 may include a lever 104. When a user operates the wall switch 102, the user feels the movement of the lever 104. FIG. 1B is an illustration of a capacitive touch screen according to the prior art. A capacitive touch screen 112 of a mobile device 110 may sense the user input as a perturbance in an electrostatic field as illustrated in graph 114. This field may be processed to determine a location of a user's input. However, the user cannot feel the electrostatic field. One example that illustrates this difference is typing using a traditional keyboard versus a keyboard in a touchscreen device. With the traditional keyboard, the user can feel the action of pressing a key, which gives the user the certainty of an action taking place. With the touchscreen keyboard, the confirmation of the action must be by other means, typically an optical or sound confirmation, but not the real feel of touching.

Furthermore, interaction with conventional touch sensors is limited to the feel of the surface they are built in. As an example, when interacting with a touch screen, the human finger perceives the surface of glass. In the case of mechanical switches, when an action is desired, the user can feel the action taking place. In both examples the feedback is fixed.

Only some drawbacks to conventional electronic devices and input and output to those devices are described above. However, these drawbacks illustrate a need for further improvements in user input and user feedback to improve capability of electronic devices, such as light switches or consumer smartphones, to interact with users.

### SUMMARY

Triboelectric sensors can be used to provide interaction between an electronic device and a human through the sense of touch. A triboelectric sensor may determine an amount of force applied to the sensor by a user, such as with their hand or fingers, and translate the applied force to an electrical signal. That electrical signal may be processed and used to control operation of the electronic device. The electronic device may then provide haptic feedback to the user through the sense of touch. A haptic feedback component, such as an actuator, may be integrated with a triboelectric-based component, such as the triboelectric sensor, as part of a component in an electronic device, such as a smart phone. For example, the haptic device and the triboelectric sensor may be constructed on the same substrate such that the devices are co-located on the same substrate. Further, in some examples, the haptic device and the triboelectric sensor may be constructed on the same substrate and share a common active layer. Examples throughout this description demonstrate a novel touch sensor technology that is able to recreate the sense of touch, giving the user the feel of interaction with the touch sensor, and allow for custom, dynamic feedback not possible with mechanical switches.

Touch sensing capabilities of devices described herein are possible with devices that use the triboelectric effect. In some examples, a triboelectric-based sensor can be self-powering. The touch sensor may be integrated with a piezoelectric actuator to recreate the sense of touch through haptic feedback, such as vibration. The touch sensor with haptic feedback can be fabricated on either rigid or flexible substrates. Having a mechanically flexible touch sensor with haptic feedback allows the design of lighter, smaller, more elegant touch interfaces. Devices constructed in accordance with the examples described herein can be used to replace mechanical switches in appliances, car consoles, peripheral input devices (e.g., keyboards, keypads, etc.).

In some example devices described herein, the sensor may be a thin film device. Furthermore, the touch sensor can also be used as a force sensor to allow more than simple binary on/off input from a user. As an example, the first touch event recorded by the system can be used to turn on a car's stereo, and subsequent touch events with increasing force can be used to increase the volume. Feedback regarding these inputs can be provided to the user through haptic feedback to recreate the actual feel of pressing or interacting with a switch. For example, each time a user touches the switch, a small vibration may be generated nearly instantaneously with the touch. As the user presses harder, the vibration may likewise increase in amplitude.

A touch/force sensor using triboelectric thin films may be incorporated into consumer electronic devices, such as mobile devices, power switches, volume controls, or other input device. The applications are not limited to those described, but can be used, for example, as a substitute or supplement to any mechanical switch. Still other example uses for triboelectric-based sensors include mechanical switches in vehicles (e.g., engine start, doors, windows, seats, etc.).

According to one embodiment, an apparatus may include a triboelectric-based component on a substrate, and a haptic feedback component co-located on the same substrate and configured to operate in conjunction with the triboelectric-based component.

According to another embodiment, a method of operating an electronic input device having a triboelectric-based component and a haptic feedback component co-located on a substrate may include the steps of receiving an input signal from the triboelectric-based component on the substrate and generating an output signal to actuate the haptic feedback component on the substrate.

According to a further embodiment, an apparatus may include a user input device, such as a switch, that includes a triboelectric-based component on a substrate, and a haptic feedback component co-located on the same substrate and configured to operate in conjunction with the triboelectric-based component.

According to yet another embodiment, a wireless keyboard may include a plurality of keys, each key including a triboelectric-based component on a substrate, and a haptic feedback component co-located on the same substrate and configured to operate in conjunction with the triboelectric-based component. The wireless keyboard may also include a wireless communications module coupled to the plurality of keys and configured to transmit user input received at the plurality of keys through the triboelectric-based component of each of the plurality of keys.

The triboelectric thin film layer may include at least one of a perfluoronated copolymer, polyvinylidene fluoride (PVDF), a copolymer of PVDF, polydimethylsiloxane (PDMS), poly(methyl methacrylate) (PMMA), polytetrafluoroethylene (e.g., Teflon™), polymer foam, poly(methyl methacrylate)-co-poly(1H,1H-perfluoroctyl methacrylate), a fluorinated polymer, and an electronegative polymer. The triboelectric thin film may be modified to increase a friction coefficient, such as by forming a plurality of pillars, either similarly- or differently-sized, on the thin film. The triboelectric-based sensor and other parts, or all of, the triboelectric-based sensor may be flexible. For example, the sensor or apparatus may be formed on at least one of polyethylene terephthalate (PET), polyethylene naphthalate (PEN), polycarbonate (PC), PMMA, polyimide, and/or another thermoplastic material. In some embodiments, the substrate may also be transparent.

The triboelectric thin film for the triboelectric-based sensor may be manufactured by now or future-developed manufacturing processes. In some embodiments, the triboelectric thin film may be a perfluoronated copolymer, or other statistical copolymer, synthesized by free radical polymerization in a non-polar solvent (e.g., benzene). In one embodiment, the perfluoronated copolymer may include poly(methyl methacrylate)-co-poly(1H,1H-perfluoroctyl methacrylate), which may be synthesized via free radical polymerization under inert atmosphere conditions. In some embodiments, the perfluoronated copolymer has a molecular weight of approximately 10,000-50,000 and a dispersion ratio of approximately 1.5-2.5. In some embodiments, the perfluoronated copolymer has a controlling perfluoro segment in proportion by weight of more than approximately fifty percent.

The triboelectric-based sensor or apparatus may execute steps to facilitate the processing and transmission of user input received at the triboelectric-based sensor. A processor, or other logic circuitry, may be configured through hardware, software, and/or firmware to execute steps including: receiving, at a triboelectric-based sensor of a touch device, an applied force; converting, at the triboelectric-based sensor of the touch device, the applied force to an electric signal; transmitting, by the triboelectric-based sensor of the touch device, the electric signal to logic circuitry, such as an application processor; generating by the logic circuitry, a haptic feedback signal in response to and/or based on the electric signal; and/or outputting the haptic feedback signal to a haptic feedback device.

The foregoing has outlined rather broadly certain features and technical advantages of embodiments of the present invention in order that the detailed description that follows may be better understood. Additional features and advantages will be described hereinafter that form the subject of the claims of the invention. It should be appreciated by those having ordinary skill in the art that the conception and specific embodiment disclosed may be readily utilized as a basis for modifying or designing other structures for carrying out the same or similar purposes. It should also be realized by those having ordinary skill in the art that such equivalent constructions do not depart from the spirit and scope of the invention as set forth in the appended claims. Additional features will be better understood from the following description when considered in connection with the accompanying figures. It is to be expressly understood, however, that each of the figures is provided for the purpose of illustration and description only and is not intended to limit the present invention.

### BRIEF DESCRIPTION OF THE DRAWINGS

For a more complete understanding of the disclosed system and methods, reference is now made to the following descriptions taken in conjunction with the accompanying drawings.

FIG. 1A is an illustration of a mechanical switch according to the prior art.

FIG. 1B is an illustration of a capacitive touch screen according to the prior art.

FIG. 2 is an illustration of a triboelectric-based sensor with haptic feedback according to some embodiments of the disclosure.

FIG. 3 is a block diagram illustrating an apparatus with a triboelectric-based sensor co-located on a substrate with a haptic feedback actuator according to some embodiments of the disclosure.

FIG. 4 is a flow chart illustrating an example method for operating a triboelectric-based sensor according to some embodiments of the disclosure.

FIG. 5 is a cross-sectional view of a triboelectric-based sensor co-located on a substrate with a haptic feedback actuator according to some embodiments of the disclosure.

FIG. 6A is a block diagram illustrating a triboelectric-based sensor and haptic feedback actuator co-located on a substrate with a shared electrode according to some embodiments of the disclosure.

FIG. 6B is a block diagram illustrating a triboelectric-based sensor co-located on a substrate with several haptic feedback actuators with a shared electrode according to some embodiments of the disclosure.

FIG. 6C is a block diagram illustrating a triboelectric-based sensor co-located on a substrate with another arrangement of haptic feedback actuators according to some embodiments of the disclosure.

FIG. 7A is a cross-sectional view illustrating thin films for a triboelectric-based sensor having an electronegative triboelectric layer according to some embodiments of the disclosure.

FIG. 7B is a cross-sectional view illustrating thin films for a double-sided triboelectric-based sensor having an electropositive triboelectric layer according to some embodiments of the disclosure.

FIG. 7C is a cross-sectional view illustrating thin films for a haptic feedback actuator with two thin film electrodes according to some embodiments of the disclosure.

FIG. 8 is a block diagram illustrating a system for receiving input and providing haptic feedback according to some embodiments of the disclosure.

FIG. 9 is a top-down view illustrating an array of triboelectric-based sensors co-located on a substrate with an array of haptic feedback actuators according to some embodiments of the disclosure.

FIG. 10A is a top-down view illustrating a paired triboelectric-based sensor and haptic feedback actuator according to some embodiments of the disclosure.

FIG. 10B is a top-down view illustrating a paired triboelectric-based sensor and haptic feedback actuator vertically integrated according to some embodiments of the disclosure.

FIG. 10C is a top-down view illustrating a paired triboelectric-based sensor and haptic feedback actuator with the sensor partially surrounding the actuator according to some embodiments of the disclosure.

FIG. 11 is a cross-sectional view illustrating a vertically integrated triboelectric-based sensor and haptic feedback actuator according to embodiments of the disclosure.

FIG. 12 is a graph illustrating displacement as a function of applied voltage for a piezoelectric material according to some embodiments of the disclosure.

FIG. 13 is a graph illustrating power consumption as a function of applied voltage for a 15 μm PVDF-co-trifluoroethylene (PVDF-TrFE) piezoelectric material according to some embodiments of the disclosure.

FIG. 14 is a graph illustrating power consumption as a function of applied voltage for a 15 μm PVDF-TrFE-chlorofluoroethylene terpolymer (CFE) piezoelectric material according to some embodiments of the disclosure.

FIG. 15 is a graph illustrating power consumption as a function of applied voltage for a 15 μm PVDF-TrFE piezoelectric material according to some embodiments of the disclosure.

FIG. 16 is a graph illustrating power consumption as a function of applied voltage for a 30 μm PVDF-TrFE piezoelectric material according to some embodiments of the disclosure.

FIG. 17 is a graph illustrating displacement magnitude as a function of frequency according to some embodiments of the disclosure.

FIG. 18 is a block diagram illustrating a system for receiving input and providing haptic feedback with a wireless connection according to some embodiments of the disclosure.

FIG. 19 is a block diagram illustrating a wireless keyboard for a mobile computing device using a triboelectric-based sensor co-located on a substrate with a haptic feedback actuator according to some embodiments of the disclosure.

FIG. 20 is a block diagram illustrating a system for receiving input and providing haptic feedback with a wireless connection according to some embodiments of the disclosure.

FIG. 21 is a block diagram illustrating a wireless switch for operating electronics using a triboelectric-based sensor co-located on a substrate with a haptic feedback actuator according to some embodiments of the disclosure.

FIG. 22 is a block diagram illustrating a wireless switch for operating electronics using a triboelectric-based sensor co-located on a substrate with a haptic feedback actuator according to some embodiments of the disclosure.

FIG. 23 is a block diagram illustrating an apparatus with a triboelectric-based sensor according to one embodiment of the disclosure.

FIG. 24 is a top-down view of a triboelectric-based sensor with thin film resistor according to one embodiment of the disclosure.

FIG. 25A is an illustration of an example mobile device incorporating a triboelectric-based sensor co-located on a substrate with a haptic feedback actuator in a control button according to some embodiments of the disclosure.

FIG. 25B is an illustration of an example mobile device incorporating a triboelectric-based sensor co-located on a substrate with a haptic feedback actuator in a display screen according to some embodiments of the disclosure.

FIG. 25C is an illustration of an example mobile device incorporating a triboelectric-based sensor co-located on a substrate with a haptic feedback actuator in a directional control pad according to some embodiments of the disclosure.

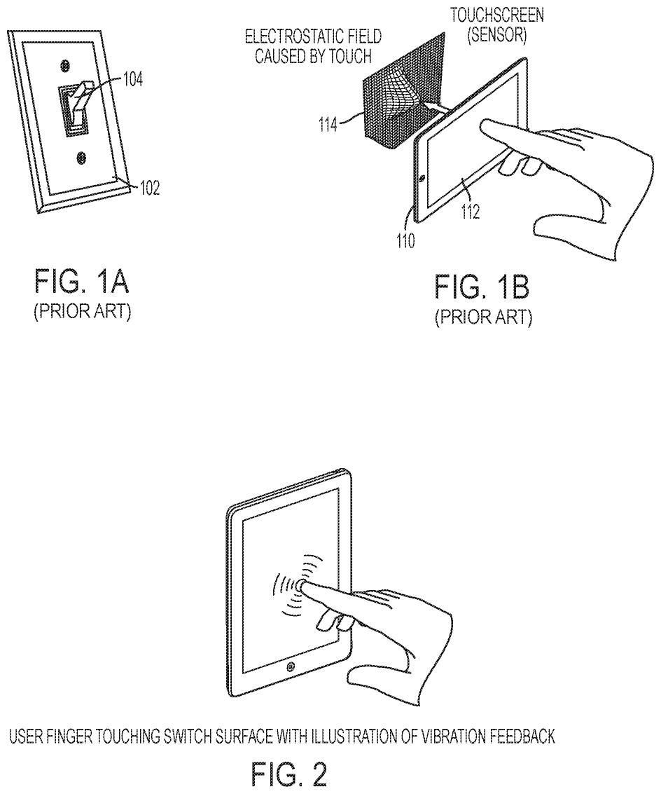

### DETAILED DESCRIPTION

FIG. 2 is an illustration of a triboelectric-based sensor with haptic feedback according to some embodiments of the disclosure. A mechanical switch may be replaced with a triboelectric-based sensor. However, a thin film sensor, such as the triboelectric sensor, lacks a physical feedback to the user. With a conventional mechanical switch, the user is provided feedback through the movement of the lever. A triboelectric-based sensor may include a haptic feedback device, such as an actuator, to provide feedback to the user operating the triboelectric-based sensor. For example, when a user touches the triboelectric-based sensor, the haptic feedback device may vibrate to provide touch sensation to the user indicating that the user's input was received. The triboelectric-based sensor and the haptic feedback device may be thin film devices, and, thus allow an electronic device, such as a wall switch, to have a low profile. The triboelectric-based sensor and the haptic feedback device may be co-located on the same substrate and/or share an active layer. Configurations for an electronic device, such as the switch illustrated in FIG. 2, are described further below.

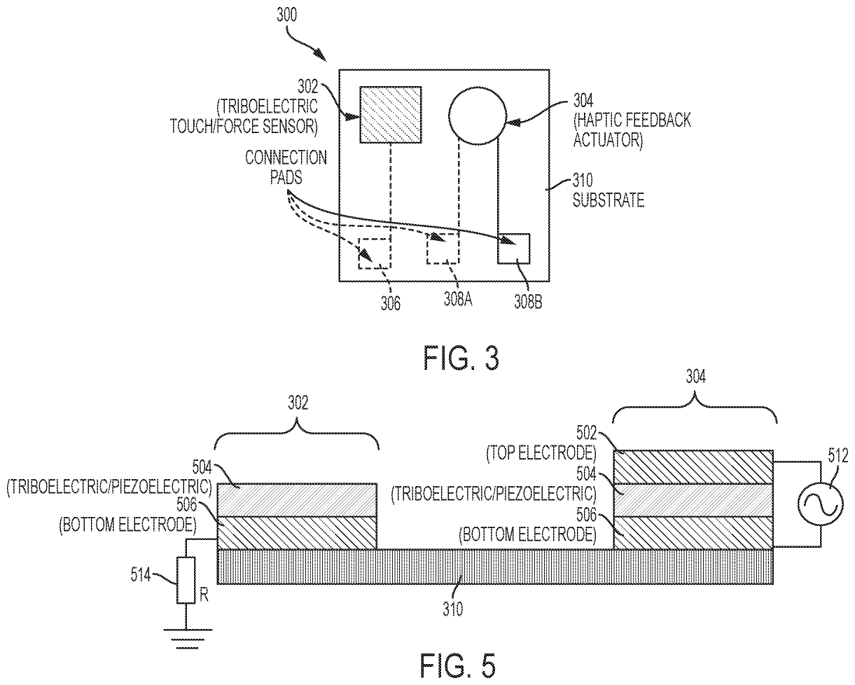

FIG. 3 is a block diagram illustrating an apparatus with a triboelectric-based sensor co-located on a substrate with a haptic feedback actuator according to some embodiments of the disclosure. Apparatus 300 may include force sensor 302, an integrated circuit (IC) (not shown) coupled to sensor 302, and haptic feedback actuator 304 on substrate 310. Substrate 310 may be one of PET, PEN, PC, PMMA, polyimide, poly(p-xylylene) polymer (e.g., Parylene-C), other thermoplastic materials, or other flexible or inflexible substrate material. Electrode 306 may couple sensor 302 to logic circuitry, such as to an application processor or to an interface to an application processor. Electrodes 308A-B may couple actuator 304 to logic circuitry, such as the same application processor or interface coupled to electrode 306. More or less electrodes may be used to couple circuitry to sensor 302 and actuator 304 based on other factors involved in the design of apparatus 300. In one example, a single electrode may be used to couple to sensor 302 and actuator 304 in place of electrodes 306 and 308A. Electrodes 306 and 308A-B may be made of aluminum, copper, silver, indium tin oxide (ITO), tin oxide, fluorine-doped tin oxide, aluminum-doped zinc oxide, gallium-doped zinc oxide, PEDOT:PSS, or another conductive material or alloy. Apparatus 300 may be sized based on an intended use, amount of force anticipated, and/or manner of application of force. In one example, apparatus 300 may be suited for interaction with a single human finger pad or fingertip with a size of between approximately 5 mm and approximately 25 mm on a length and/or width, or at least, equal to, or between any two of 5 mm, 10 mm, 15 mm, 20 mm, and 25 mm.

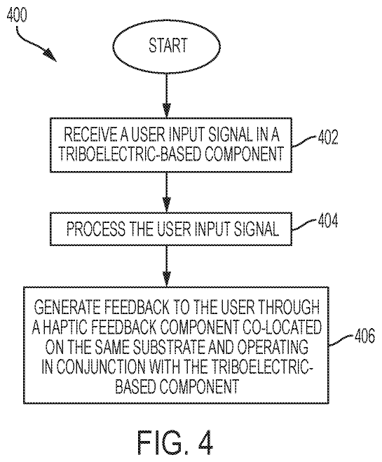

The co-located triboelectric-based sensor and haptic feedback actuator may be controlled to receive user input and provide responsive feedback to the user. A method for operating a co-located sensor and actuator, such as in the apparatus of FIG. 3, is shown in FIG. 4. FIG. 4 is a flow chart illustrating an example method for operating a triboelectric-based sensor according to some embodiments of the disclosure. Method 400 may begin at block 402 with receiving a user input signal from a triboelectric-based sensor. The user input signal may be, for example, an analog waveform generated by the sensor or a digital signal obtained by processing the sensor output. Next, at block 404, the user input signal may be processed to determine, for example, how much force a user exerted on the sensor, where in an array of sensors the user touched, or the like. Then, at block 406, a feedback signal may be generated to control a haptic feedback actuator that is co-located on the same substrate with the triboelectric-based component.

The triboelectric-based sensor may be operated in conjunction with the haptic feedback actuator, such that feedback in the actuator is intended to convey to the user a sense that the input has been received. In such an example, feedback may be generated automatically in response to the receiving of the user input signal at block 402. Furthermore, the feedback signal may be generated based on the user input signal. For example, an amplitude of haptic feedback may be based on an amplitude of force received at the triboelectric-based sensor. The haptic feedback actuator may also or alternatively be used to provide substantive feedback from operations other than the mere acknowledgement of user input. For example, the processing at block 404 may determine if the user provides input at an incorrect time or location, and generate haptic feedback at block 406 that provides vibration near the user's finger to indicate the incorrect feedback. One application of such feedback may be vibration feedback when a user answers a question incorrectly in a quiz game.

The triboelectric sensors with haptic feedback may be constructed from thin films as shown in the example of FIG. 5. FIG. 5 is a cross-sectional view of a triboelectric-based sensor co-located on a substrate with a haptic feedback actuator according to some embodiments of the disclosure. In some embodiments, the sensor and the actuator may share an active material layer. For example, one layer may function as a triboelectric layer in one device and a piezoelectric layer in another device co-located on the same substrate. The cross-section through one example of sensor 302 and actuator 304 of FIG. 3 is shown FIG. 5. Bottom electrode 506 and triboelectric layer 504 may make up sensor 302. Bottom electrode 506, triboelectric layer 504, and top electrode 502 may make up actuator 304. A stimulus, such as AC voltage source 512, may be coupled to electrodes 502 and 506 of actuator 304 to generate haptic feedback. Sense resistor 514 may be coupled to bottom electrode 506 of sensor 302 to provide signals indicative of user input received by sensor 302. In some embodiments, sense resistor 514 may be a thin film resistor co-located on substrate 310 with sensor 302 and actuator 304.

Triboelectric/piezoelectric layer 504 may be an electronegative triboelectric layer or electropositive triboelectric layer. Examples of electronegative triboelectric layers include PVDF and its copolymers (e.g., PVDF-TrFE, PVDF-TrFE CFE, and PVDF-co-hexafluoropropene (HFP), PDMS, PMMA, polytetrafluoroethylene (e.g., TEFLON), polymer foams, poly(methyl methacrylate)-co-poly(1H,1H-perfluoroctyl methacrylate), and other electronegative polymers. Examples of electropositive triboelectric layers include human hands (such as when only a single electrode is coupled to the triboelectric layer), acetate, mica, polyimides (e.g., nylon), and other electropositive polymers. Examples of piezoelectric layers include PVDF and its copolymers (PVDF-TrFE, PVDF-TrFE CFE, and PVDF-HFP), Parylene-C, cellular polypropylene, cellular PEN, voided charged polymers, polymer-based electrets, piezoelectric composite materials having a polymeric matrix, and other materials that exhibit the piezoelectric effect. In some configurations, both the touch sensor and haptic feedback actuator may be made of the same active polymeric material. For example, the same piezoelectric material that forms the actuator may be used as the triboelectric layer in the touch sensor when the piezoelectric material is electronegative. In some configurations, different active materials may be used for the touch sensor and the haptic feedback actuator, such as the materials listed above.

Sensor 302 and actuator 304 may be formed by a combination of photolithography and deposition steps. For example, each of layers 506, 504, and 502 may be deposited on substrate 310 and subsequently patterned to form individual sensor 302 and actuator 304. As another example, a sacrificial layer may be deposited on substrate 310 and patterned to form openings corresponding to sensor 302 and actuator 304. Layers 506, 504, and 502 may be deposited in the openings, and the sacrificial layer lifted off to leave sensor 302 and actuator 304. Other manufacturing processes are possible for forming sensor 302 and actuator 304, such as thin film deposition and patterning methods, screen and ink jet printing, chemical vapor deposition, physical vapor deposition, and solution processing methods. When manufacturing sensor 302 and actuator 304 on a flexible substrate, processing steps may be limited based on the use of the flexible substrate, such as by having a maximum processing temperature of 135 degrees Celsius.

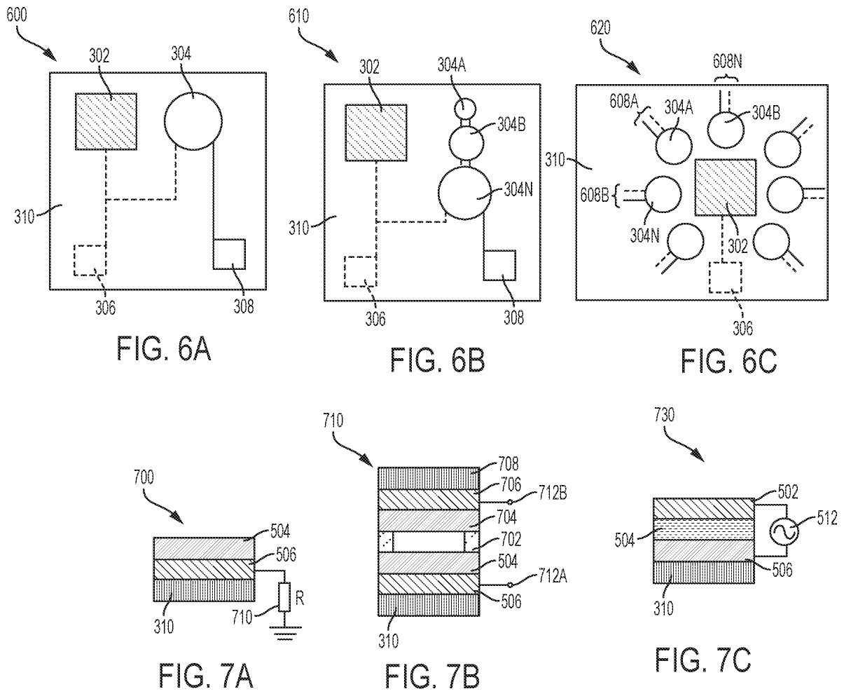

The triboelectric-based sensor and haptic feedback actuators may have different arrangements than that shown in FIG. 3. The system can be formed of a single touch sensor and a single haptic actuator as shown in FIG. 6A, a single touch sensor and a number of haptic actuators with different or same dimensions connected in series as shown in FIG. 6B, a single touch sensor with multiple independent haptic feedback actuators as shown in FIG. 6C, multiple touch sensors with a single actuator, multiple actuators, or any other possible combination in which both the touch sensing and haptic feedback are integrated in a particular area. FIGS. 6A, 6B, and 6C illustrate different arrangements of sensors and actuators. However, none of these are limiting examples. The arrangement of sensors and actuators may be selected based on consumer device requirements and features.

FIG. 6A is a block diagram illustrating a triboelectric-based sensor and haptic feedback actuator co-located on a substrate with a shared electrode according to some embodiments of the disclosure. System 600 may include triboelectric-based sensor 302 and haptic feedback actuator 304 co-located on substrate 310. Although shown positioned laterally adjacent, sensor 302 and actuator 304 may be in different configurations, such as off-center from each other, aligned along another axis, or aligned diagonally. Furthermore, although two electrodes 306 and 308 are shown with electrode 306 shared between sensor 302 and actuator 304, a different number of electrodes may be present.

FIG. 6B is a block diagram illustrating a triboelectric-based sensor co-located on a substrate with several haptic feedback actuators with a shared electrode according to some embodiments of the disclosure. System 610 may include triboelectric-based sensor 302 and haptic feedback actuators 304A-304N. Haptic feedback actuators 304A-304N may be coupled in series with electrodes 306 and 308 in a “snowman” configuration. In another example, haptic feedback actuators 304A-304N may be connected in parallel or in a combination of series and parallel. Although shown positioned laterally adjacent, sensor 302 and haptic feedback actuators 304A-304N may be in different configurations, such as off-center from each other, aligned along another axis, or aligned diagonally. Furthermore, although two electrodes 306 and 308 are shown with electrode 306 shared between sensor 302 and actuator 304, a different number of electrodes may be present.

FIG. 6C is a block diagram illustrating a triboelectric-based sensor co-located on a substrate with another arrangement of haptic feedback actuators according to some embodiments of the disclosure. System 620 may include triboelectric-based sensor 302 and haptic feedback actuators 304A-304N. The haptic feedback actuators 304A-304N may be individually addressable by each actuator by having a separate pair of leads 608A-608N. Although shown positioned in a circular configuration, sensor 302 and haptic feedback actuators 304A-304N may be in different configurations, such as off-center from each other, aligned along an axis, or aligned diagonally. Furthermore, haptic feedback actuators 304A-304N may be arranged in a star, X-shape, oval, rectangle, square, triangle, or other shape.

Configurations for the thin films that make up the triboelectric-based sensor and haptic feedback actuator may take on one of many forms regardless of the topological configuration of the sensor and actuator shown in the top-down views of FIG. 6A, FIG. 6B, and FIG. 6C. Some example thin film configurations are shown in FIG. 7A, FIG. 7B, and FIG. 7C.

FIG. 7A is a cross-sectional view illustrating thin films for a triboelectric-based sensor having an electronegative triboelectric layer according to some embodiments of the disclosure. Layered stack 700 may include a suitable triboelectric material 504 on top of a suitable conductive material (e.g., electrode) 506, on top of suitable substrate 310, to form a single electrode touch/force sensor used in example apparatuses, systems, and devices described herein. Triboelectric layer 504 may be, for example, an electronegative triboelectric layer. In some device configurations, resistor 710, which may be a thin film resistor, may be coupled to the electrode to convey an electric signal from triboelectric layer 504 to other circuitry.

Another example triboelectric-based touch sensor can have a dual electrode configuration such as depicted in FIG. 7B. FIG. 7B is a cross-sectional view illustrating thin films for a double-sided triboelectric-based sensor having an electropositive triboelectric layer according to some embodiments of the disclosure. In layer stack 710 a physical gap, created by the use of suitable spacer 702, exists between second triboelectric layer 704 underneath a second conductive material (e.g., electrode) 706, which is underneath a second substrate 708. Triboelectric layer 704 may be, for example, an electropositive triboelectric layer. Touch sensor operation may be based in the principle of contact electrification, in which charges are generated when two materials with opposite electro affinity make contact. For example, charges may be generated when a human finger touches the triboelectric layer because of the principle of contact electrification (e.g., tribo-electrification). Electrode contacts 712A and 712B may be coupled to electrodes 506 and 706, respectively.

FIG. 7C is a cross-sectional view illustrating thin films for a piezoelectric-based haptic feedback actuator with two thin film electrodes according to some embodiments of the disclosure. In layered stack 730, suitable piezoelectric material 504 is situated between two suitable conductive layers (e.g., bottom and top electrodes) 502 and 506. Upon the application of an alternating electric field such as from AC signal source 512, piezoelectric layer 504 changes its volume to create an intrinsic vibration that can be used to recreate the sense of touch. The amplitude and frequency of AC signal source 512 may be adjusted to provide custom, dynamic haptic feedback.

In one scenario, both the touch sensor and haptic feedback actuator can be made of the same active polymeric material. In one example, the same piezoelectric material that forms the actuator may be used as the triboelectric layer in the touch sensor. In such a configuration, the piezoelectric material may be electronegative. In another example, different active materials may be used for the touch sensor and the haptic feedback actuator.

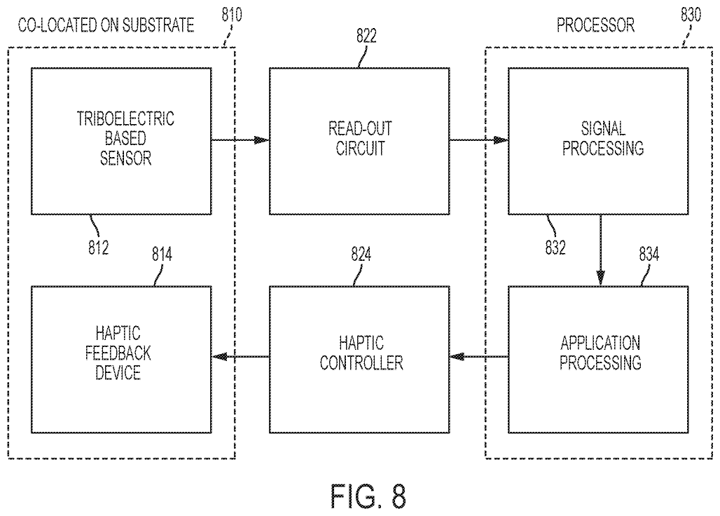

FIG. 8 is a block diagram illustrating a system for receiving input and providing haptic feedback according to some embodiments of the disclosure. In system 800, triboelectric-based sensor 812 may be coupled to read-out circuit 822. The triboelectric-based touch sensor can have any of the features described in International Patent Applications PCT/IB2017/053471 and PCT/IB2017/053473, which are hereby incorporated by reference herein. Read-out circuit 822 may receive signals from electrodes of triboelectric-based sensor 810. Read-out circuit 822 may be configured to address individual sensors in an array and/or to interpret signals received from sensors 812. A user input signal may be produced by read-out circuit 822 and output to signal processing block 832 of processor 830.

Processor 830 may include signal processing block 832 and application processing block 834, among other functionality. Signal processing block 832 may process the user input signal to improve signal characteristics, such as signal-to-noise ratio, and/or determine a user input. For example, signal processing block 832 may determine a portion of a display screen touched by a user. As one example, signal processing block 832 may determine, based on user input to sensor 810, that the user provided input to an “OK” button in a pop-up message box. As another example, signal processing block 832 may determine based on user input to an array of sensors 810 that a user swiped upwards, forwards, backwards, or downwards across the screen. Application processing block 834 may take action based on the user input detected in signal processing block 834. For example, application processing block 834 may cause a mobile application executing on a smart phone to close the pop-up message box when the user input is pressing the “OK” button in the pop-up message box. As another example, application processing block 834 may cause a mobile application executing on a smart phone to move to a next or previous page of content when the user input is a upwards, forwards, backwards, or downward swipe. As part of execution of an application, application processing block 834 may cause haptic feedback to be provided to the user.

When haptic feedback is desired, application processing block 834 may operate haptic controller 824 to actuate haptic feedback devices 814. Haptic controller 824 may include a driver, having a signal generator, power amplifier, and the appropriate circuitry to enable both. In some embodiments, haptic controller 824 is implemented using conventional silicon-based electronics and/or embedded within the active layer film using thin film circuitry. When an array of haptic feedback devices are present, haptic controller 824 may include circuitry for addressing individual haptic feedback devices and controlling the addressed device or devices to produce the haptic feedback indicated by application processing block 834. Different stimuli can be recreated by haptic controller 824. Vibration of feedback device 814 can be controlled by the shape (e.g., step function, sinusoidal, pulsed, etc.), frequency (e.g., ranging from 1 Hz to 100,000 Hz), amplitude (e.g., from 20 V to 200 V) and/or duty cycle of a drive signal sent to device 814.

Modules 822, 824, 832, and/or 834 may include circuitry configured to perform the operations described herein. In some embodiments, the modules are implemented on a general purpose processor or digital signal processor and may include software code that when executed cause the processor to perform the operations described herein. In some embodiments, the circuitry or other hardware may be configured using firmware.

Different sensations can be recreated by providing particular drive signals to a haptic feedback device (e.g., by changing between a step function, a sinusoidal function, and a pulse function), but different sensations can also be provided from actuators with different geometries and/or sizes (as shown in FIG. 6B and FIG. 6C), in which the different feedback devices can deliver different forces, thus resulting in different sensations to the user. Another configuration may include actuators operating independently (as shown in FIG. 6C) with different input signals, such as to provide for feedback localization in a given area (e.g., by selectively activating some actuators to stimulate localized sections of a finger pad).

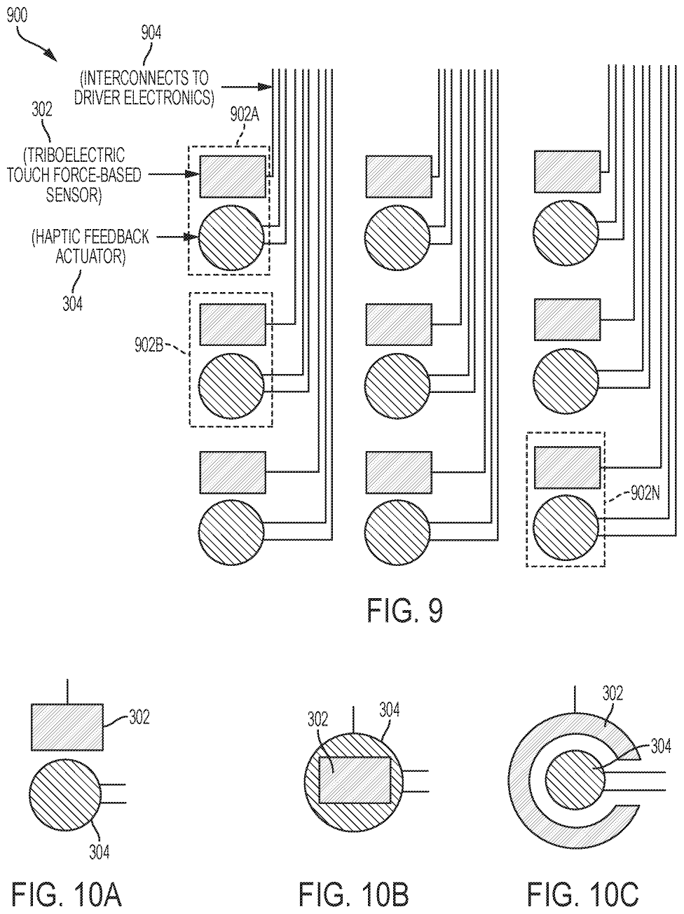

To provide additional features, improved sensitivity, or other features, haptic feedback actuators and triboelectric-based sensors may be organized into arrays. The arrays may be accessed through, for example, the haptic controller and read-out circuit of FIG. 8. One example of such an array of sensors and actuators is shown in FIG. 9. FIG. 9 is a top-down view illustrating an array of triboelectric-based sensors co-located on a substrate with an array of haptic feedback actuators according to some embodiments of the disclosure. Array 900 may include triboelectric-based sensors 302 and haptic feedback actuators 304 coupled through interconnects 904 to driver and/or read-out circuitry. The read-out circuitry may include a multiplexer. The multiplexer may be configured to provide individual addressing of components in array 900. One triboelectric-based sensor 302 may be associated with one or more haptic feedback actuators 304 in a group 902A. One or more groups 902A, 902B, . . . , 902N may be used in array 900 of an electronic device. An array of sensors, such as the groups 902A-N, may be used to obtain touch resolution from approximately 1 mm to 15 mm or any value there between over a surface area of a switch or other electronic device (e.g., at least one square centimeter).

Some example configurations of group 902A of a haptic feedback actuator and triboelectric-based sensor are shown in FIG. 10A, FIG. 10B, and FIG. 10C. FIG. 10A is a top-down view illustrating a paired triboelectric-based sensor and haptic feedback actuator according to some embodiments of the disclosure. In FIG. 10A, touch sensor 302 has a square geometry and haptic feedback device 304 is shown with a circular geometry, with the touch sensor adjacent to or in close proximity to the haptic feedback device. FIG. 10B is a top-down view illustrating a paired triboelectric-based sensor and haptic feedback actuator vertically integrated according to some embodiments of the disclosure. In FIG. 10B, touch sensor 302 is on top of haptic feedback actuator 304. FIG. 10C is a top-down view illustrating a paired triboelectric-based sensor and haptic feedback actuator with the sensor partially surrounding the actuator according to some embodiments of the disclosure. In FIG. 10C, each of haptic feedback actuator 304 and triboelectric-based sensor 302 have circular geometries, with the actuator 304 being at a center and the touch sensor 302 at least partially surrounding the actuator 304 in a ring-like configuration.

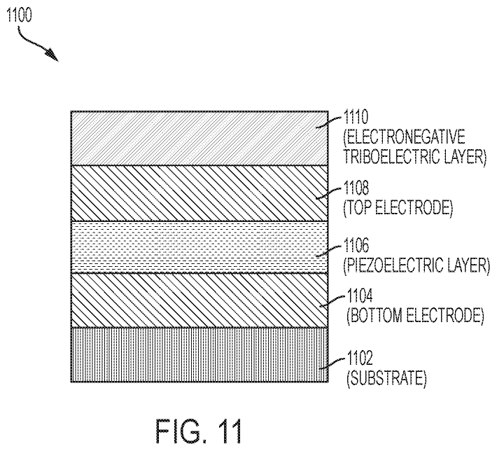

In embodiments configured with a haptic feedback actuator stacked on a sensor as shown in FIG. 10B, the sensor and actuator may share layers, such as a conductive electrode layer as shown in FIG. 11. FIG. 11 is a cross-sectional view illustrating a vertically integrated triboelectric-based sensor and haptic feedback actuator according to embodiments of the disclosure. Stack 1100 illustrates substrate 1102 with bottom electrode 1104, haptic feedback active layer 1106 (e.g., a piezoelectric layer), top electrode 1108, and triboelectric-based layer 1110 (e.g., an electronegative triboelectric layer).

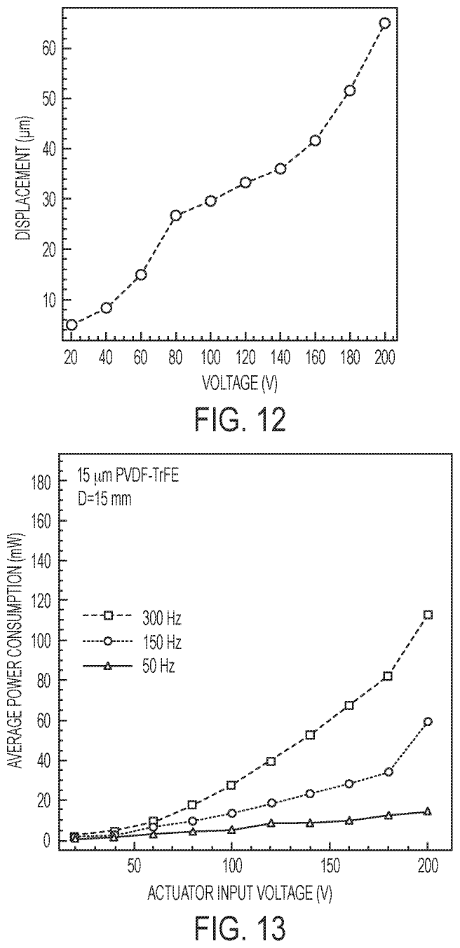

Sample devices have been fabricated and characteristics of those sample devices measured. For example, a device was fabricated with a 30 micrometer thick PVDF-TrFE layer active piezoelectric material. The displacement as a function of applied voltage of a 50% duty cycle square wave was measured and is shown in FIG. 12. FIG. 12 is a graph illustrating displacement as a function of applied voltage for a piezoelectric material according to some embodiments of the disclosure. At approximately 20 V, the sample actuator exhibits a displacement of 4.9 μm with a maximum displacement of 65 μm at 200 V. The relationship between displacement and voltage is generally linear between 20-200 Volts. The lower limit of detectability for a human finger is 0.2 μm. Thus, the sample device provides sufficient displacement for providing haptic feedback to a human user. The values of displacement for a sample device may be manipulated to have more or less displacement. For example, if lower displacement values are desired, a weight may be added to the actuator to decrease displacement.

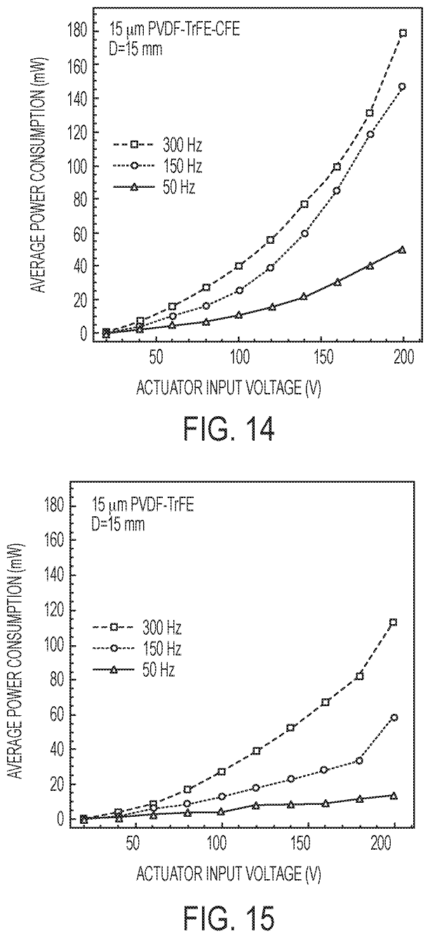

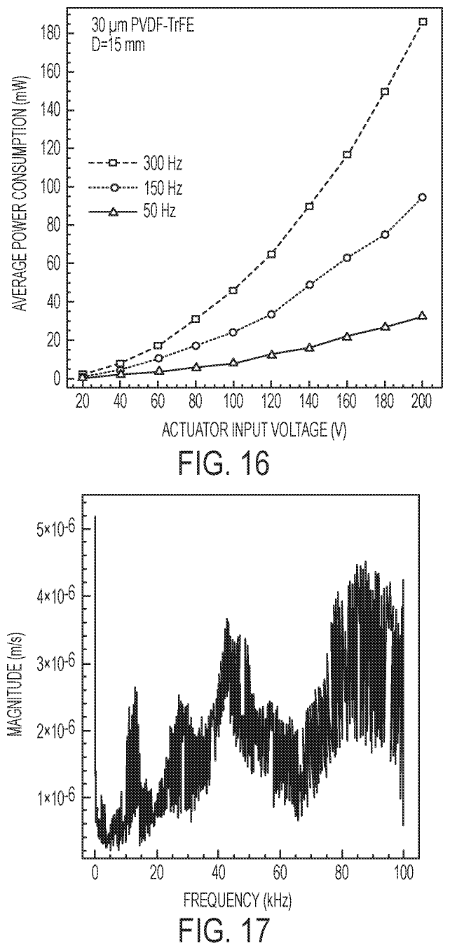

Power consumption can be a consideration in the design of electronic devices, particularly passive devices or mobile devices operating from battery power. FIG. 13 and FIG. 14 show average power consumption of sample devices, as a function of the input voltage and for three different frequencies. FIG. 13 is a graph illustrating power consumption as a function of applied voltage for a 15 μm PVDF-TrFE piezoelectric material according to some embodiments of the disclosure. FIG. 14 is a graph illustrating power consumption as a function of applied voltage for a 15 μm PVDF-TrFE-CFE piezoelectric material according to some embodiments of the disclosure. Even at large voltage and frequency condition (e.g., 200 V, 300 Hz) polymer-based devices show low power consumption of 118 mW for PVDF-TrFE and 180 mW for PVDF-TrFE-CFE. Power consumption may be reduced based on desired operational capabilities, such as by restricting certain sensations (and force levels). Power consumption may be restricted such as by limiting input voltage and/or frequency when on battery power or when battery levels are lower than a certain threshold (e.g., below 50%). For example, input voltages may be restricted to <100 Volts unless a mobile device is plugged in. Furthermore, power consumption can be adjusted based on a thickness of the piezoelectric material, which may also change the operational capabilities of the device, as shown in FIG. 15 and FIG. 16. FIG. 15 is a graph illustrating power consumption as a function of applied voltage for a 15 μm PVDF-TrFE piezoelectric material according to some embodiments of the disclosure. FIG. 16 is a graph illustrating power consumption as a function of applied voltage for a 30 μm PVDF-TrFE piezoelectric material according to some embodiments of the disclosure.

The sample device was tested at different frequencies to determine the frequency response of the PVDF-TrFE piezoelectric material and the results are shown in FIG. 17. FIG. 17 is a graph illustrating displacement magnitude as a function of frequency according to some embodiments of the disclosure. No resonance frequency is shown between zero and 100 kHz, indicating the piezoelectric actuator can operate at frequencies as high as 100 kHz. Different frequency vibrations may be provided through the piezoelectric actuator to provide for different feedback to the user.

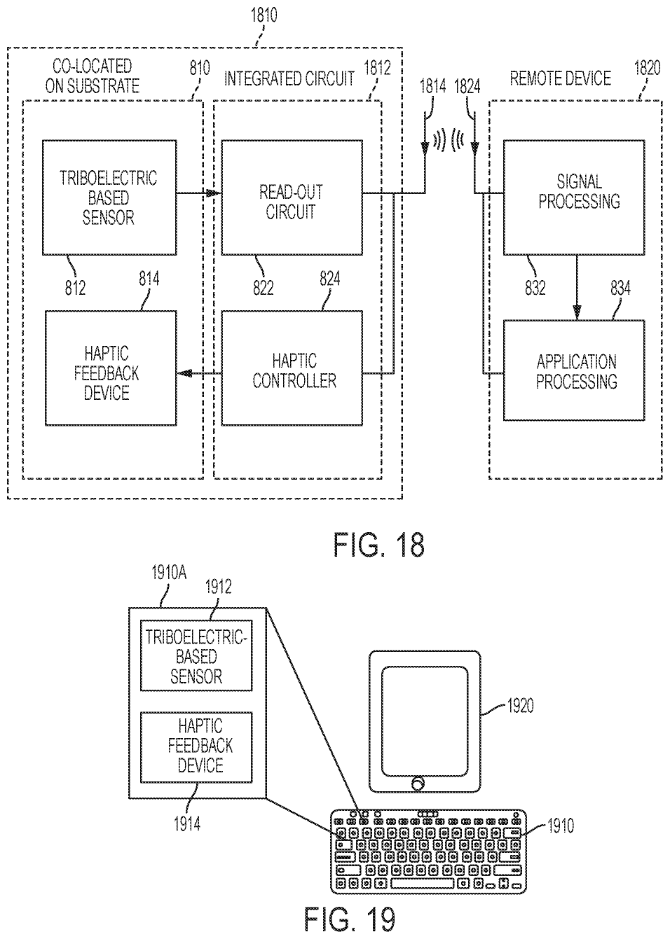

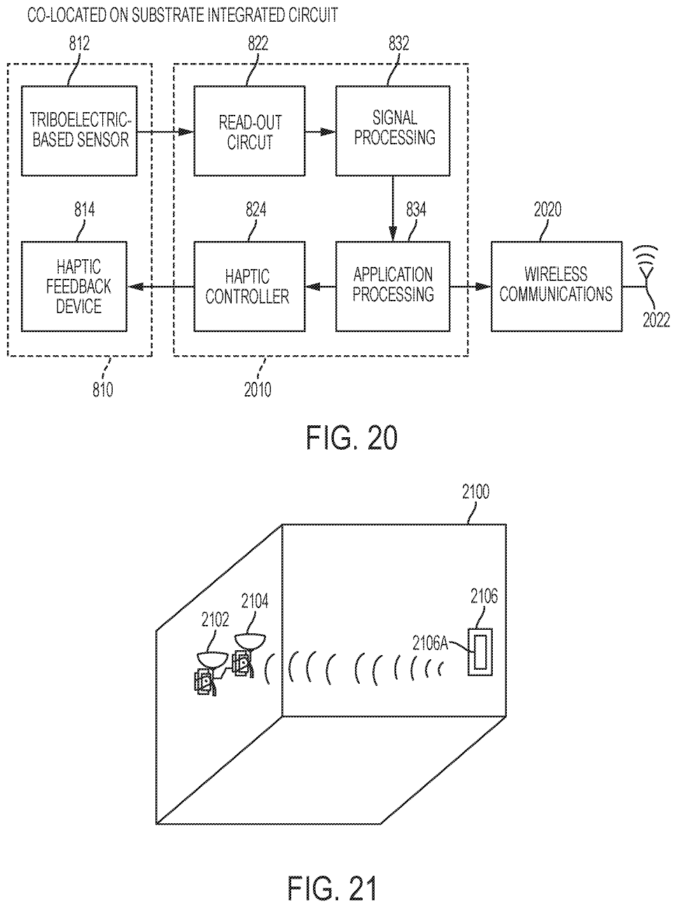

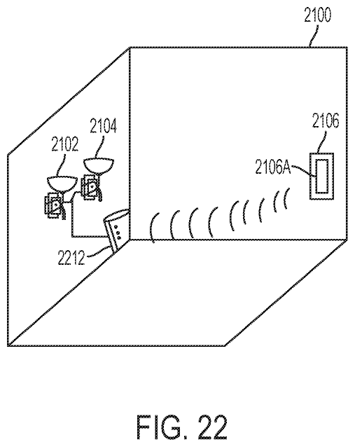

In some applications of the device, wireless communications may be integrated with the triboelectric-based sensor and haptic feedback device to allow receipt of user input by a remote processing device as illustrated in FIG. 18, FIG. 19, and FIG. 22, or control of a device based on user input remote from the device as illustrated in FIG. 20 and FIG. 21.

FIG. 18 is a block diagram illustrating a system for receiving input and providing haptic feedback with a wireless connection according to some embodiments of the disclosure. Triboelectric-based sensor 812 and haptic feedback device 814 may be co-located on a substrate 810, and in some configurations share an active layer. Co-located sensor 812 and actuator 814 may be coupled to integrated circuit 1812 with circuitry configured as read-out circuit 822 and haptic controller 824. In some embodiments, the IC 1812 may be a conventional integrated circuit or a thin film-based integrated circuit manufactured similarly to co-located sensor 812 and actuator 814. IC 1812 and co-located devices 810 may be integrated as electronic device 1810, such as a user-controlled switch. Electronic device 1810 may include an antenna 1814 for communicating with antenna 1824 of remote device 1820. Remote device 1820 may include processing capabilities for signal processing block 832 and application processing block 834. Touch/force input received at the triboelectric-based sensor 812 is received by read-out circuitry 822 and transmitted to remote device 1820. The remote device 1820 may process the user input in signal processing block 832 and determine a course of action in application processing block 834. A signal may be transmitted from the remote device 1820 back to the device 1810 to cause the haptic controller 824 to activate the haptic feedback device 814. In some configurations, haptic controller 824 may activate the haptic feedback device 814 immediately upon receipt of user input at sensor 812 to provide instantaneous feedback to the user. Haptic controller 824 may subsequently activate haptic feedback device 814 again in response to an instruction from remote device 1820. The configuration of FIG. 18 may reduce the cost of device 1810 by removing complicated logic circuitry from the device and placing that circuitry in remote device 1820. Remote device 1820 may be, for example, a smart phone or computing device that already has sufficient processing power to perform the processing required by signal processing block 832 and application processing block 834.

One example application for the configuration of FIG. 18 is a wireless keyboard for a computing device as illustrated in FIG. 19. FIG. 19 is a block diagram illustrating a wireless keyboard for a mobile computing device using a triboelectric-based sensor co-located on a substrate with a haptic feedback actuator according to some embodiments of the disclosure. Mobile computing device 1920, such as a tablet computer or a smart phone, may be coupled through a communications network to wireless keyboard 1910. Wireless keyboard 1910 may include a number of keys for letters, numbers, symbols, commands, etc., in which each key is a combination of triboelectric-based sensor 1912 and haptic feedback actuator 1914 that may be co-located on the same substrate. Wireless keyboard 1910 may be thin because there are no mechanical switches as in conventional keyboard, but instead is based on thin film technology. Even though there are no mechanical switches, the keys may generate feedback for a user similar to that of a mechanical keyboard by activating haptic feedback actuator 1914. For example, each time a user touches triboelectric-based sensor 1912 of a key, a signal indicating the pressed key or letter may be transmitted to mobile computing device 1920 and haptic feedback actuator 1914 vibrates to provide positive feedback to the user. The thin nature of wireless keyboard 1910 may improve the mobility of the keyboard without affecting user operation of the keyboard in comparison to conventional keyboard. The feedback from haptic feedback actuator 1914 of the key provides a similar physical sensation to the user as a mechanical key, but without the space and rigidity of a mechanical key. Furthermore, flexible substrates may be used for the thin film manufacturing of the sensors and actuators that make up the keys of keyboard 1910, which allows a foldable, rollable, bendable, or otherwise malleable keyboard.

Another configuration for an electronic device may integrate the processing capabilities with the sensor and actuator and wireless communications to allow some local processing of instructions and wireless transmission. FIG. 20 is a block diagram illustrating a system for receiving input and providing haptic feedback with a wireless connection according to some embodiments of the disclosure. Integrated circuit 2010 may include the read-out circuit 822, signal processing block 832, application processing block 834, and haptic controller 824. Integrated circuit 2010 may be coupled to wireless communications radio 2020 with antenna 2022. Wireless communications radio 2020 may include one or more of a Bluetooth radio, Wi-Fi radio, ZigBee radio, RFID radio, cellular radio, etc. In some configurations of IC 2010, the IC may integrate wireless communications radio 2020 and/or antenna 2022. Integrated circuit 2010 may be coupled to sensor 812 and actuator 814 co-located on substrate 810. In some configurations, integrated circuit 2010 may be built from thin films and on the same substrate (e.g., substrate 810) as sensor 812 and actuator 814. Integrating sensor 812, actuator 814, and IC 2010 in this manner may produce the smallest package size for an electronic device.

One example application for the configuration of FIG. 20 is a wireless switch for operating electronics as illustrated in FIG. 21. FIG. 21 is a block diagram illustrating a wireless switch for operating electronics using a triboelectric-based sensor co-located on a substrate with a haptic feedback actuator according to some embodiments of the disclosure. Wall switch 2106 may be located in room 2100 for operating lighting devices 2102 and 2104. Wall switch 2106 may include substrate 2106A having a triboelectric-based sensor and a haptic feedback actuator. When user input is received at the wall switch 2106, the wall switch may transmit an instruction to lighting devices 2102 and/or 2104. When pressure is applied to wall switch 2106, sensor 2106A may generate an electrical signal that is conveyed to a radio frequency (RF) communications device. The RF communications device may receive the signal, process the signal, and generate an RF signal for application to an RF antenna. The RF communications device may thus generate and/or cause transmission of a control signal based on an applied force to sensor 2106A. The control signal may be transmitted to lighting fixtures 2102 and/or 2104 to turn on or turn off fixtures 2102 and 2104 or to dim fixtures 2102 and 2106 to a level corresponding to applied force received at sensor 2106A. Although wall lighting fixtures 2102 and 2104 are illustrated in FIG. 21, wall switch 2106 may control any device in the room, including power outlets, stereo equipment, televisions, air conditioners, heaters, mobile devices, home automation systems, etc.

In some embodiments, an array of triboelectric sensors may be used in a wall switch for operating lighting fixtures. Wall switch 2106 may include a grid of triboelectric sensors. One sensor may be used to control lighting fixture 2102, while a second sensor may be used to control lighting fixture 2104. In another example, the sensors may be used to control an intensity of each fixture 2102-2104, such as when one column of sensors varies the intensity of fixture 2102 and another column of sensors varies the intensity of fixture 2104. In a further example, the sensors may be used to control color of fixtures 2102 and 2104, such as when one column of sensors varies an intensity of emitted red light, a second column of sensors varies an intensity of emitted green light, and a third column of sensors varies an intensity of emitted blue light from lighting fixtures 2102 and 2104.

Design, operation, and cost of wall switch 2106 may be simplified by moving logic circuitry from the switch to a central hub. Thus, a house that includes 25-50 wall switches would not have logic circuitry duplicated 25-50 times, but instead have logic circuitry located at a central hub as illustrated in FIG. 22. FIG. 22 is a block diagram illustrating a wireless switch for operating electronics using a triboelectric-based sensor co-located on a substrate with a haptic feedback actuator according to some embodiments of the disclosure. Hub 2212 may be located in the room to control operation of electronics in that room, or the hub may be used to control operation of electronics throughout a house or building. Hub 2212 may be hard-wired or wirelessly connected to lighting devices 2102 and 2104, as well as other electronics. User input to switch 2106 may be transmitted wirelessly to hub 2212, which includes logic circuitry and processing capability for controlling lighting devices 2102 and 2104 in response to user input received at the switch. Switch 2106 of FIG. 22 may be configured similar to device 1810 shown in FIG. 18.

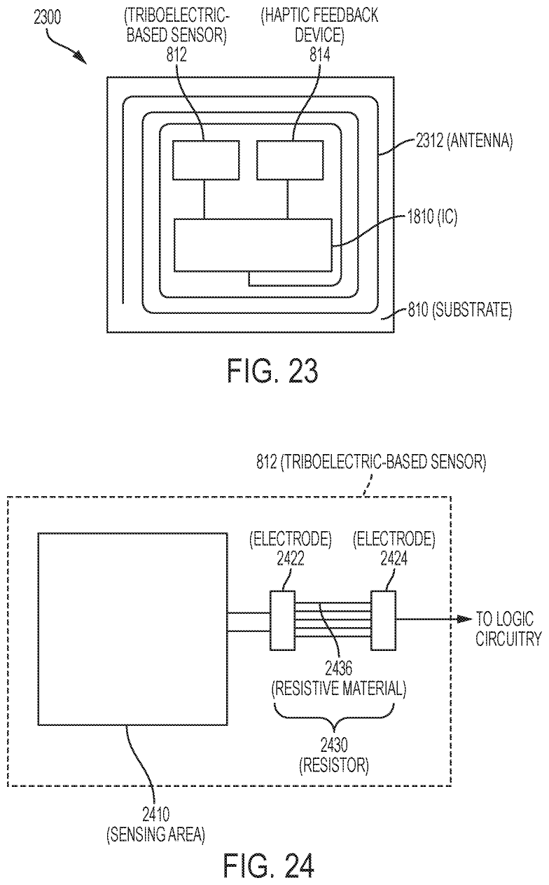

The antenna, integrated circuit, triboelectric-based sensor, and haptic feedback device may be integrated into an electronic device. FIG. 23 is a block diagram illustrating an apparatus with a triboelectric-based sensor according to one embodiment of the disclosure. Sensor 812 may receive touch/force input from a user and convey the input to IC 1810 through an electronic signal. IC 1810 may process the signal and activate haptic feedback actuator 814. IC 1810 may also transmit the determined applied force, or other values derived from the applied force, through RF antenna 2312. For example, a scaled analog value between 0 and 100 may be generated by IC 1810 based on the output signal of force sensor 812, and that scaled analog value transmitted through RF antenna 2312. In another example, a binary value of true or false may be generated by IC 1810 based on the output signal of the force sensor 812 being higher or lower than a threshold value, and that binary value transmitted through RF antenna 2312. IC 1810 may communicate using RF antenna 2312 using any wireless communications technique. In some embodiments, IC 1810 may include Bluetooth® (Bluetooth SIG, Inc. USA) functionality and operate the RF antenna 2312 according to the Bluetooth® standard. In some embodiments, IC 1810 may include WiFi functionality and operate RF antenna 2312 in accordance with the IEEE 802.11 standard. In some embodiments, IC 1810 may include frequency modulation (FM) or amplitude modulation (AM) circuitry to transmit signals through RF antenna 2312.

The triboelectric-based sensor may be integrated with a thin film resistor, such as the example sensor shown in FIG. 24. FIG. 24 is a top-down view of a triboelectric-based sensor with thin film resistor according to one embodiment of the disclosure. Force sensor 812 may include sensing area 2410 with a triboelectric layer. The triboelectric layer may be coupled to electrode 2422 of resistor 2430. Electrode 2422 may couple through a resistive material 2436 to electrode 2424 of resistor 2430. Resistor 2430 may be coupled to logic circuitry in a processor, such as integrated circuit 1810, through a contact pad or interconnect. A force applied to sensing area 2410 may generate a signal that is proportional to the force applied to sensing area 2410, which may be processed and transmitted by, for example, integrated circuit 1810. In some embodiments, force sensor 812 may be a thin film device.

Sensor 812 may include multiple triboelectric layers, which may be separated by a buffer layer, to enhance the triboelectric effect and thus produce signals with higher magnitudes for processing by IC 1810. In some embodiments, sensor 812 may include a surface modified to improve contact surface area and/or the friction coefficient between the layers in contact. In one embodiment, the modified surface may include a surface with an array of formed pillars, although other surface modifications may be used in other embodiments. The pillars may extend across a portion or the entirety of sensing area 2410. The pillars may be approximately uniformly shaped and sized, or the pillars may have different shapes and sizes.

In some embodiments, IC 1810 may include a power module, which may also be coupled to sensor 812. The power module may receive the sensor signal and distribute power. The power module may include circuitry such as power converters, DC-to-DC converters, charge pumps, and the like to convert the received sensor signal into a steady-state DC power supply.

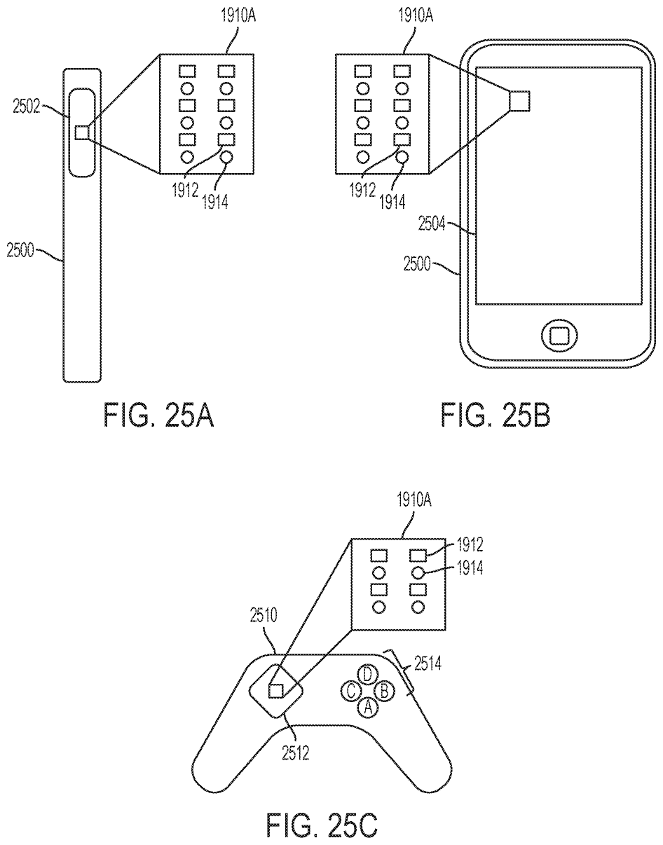

Additional examples of mobile devices incorporating haptic feedback in certain aspects of the device are shown in FIGS. 25A-C. FIG. 25A is an illustration of an example mobile device incorporating a triboelectric-based sensor co-located on a substrate with a haptic feedback actuator in a control button according to some embodiments of the disclosure. One pair of a haptic feedback actuator and a triboelectric-based sensor, or an array of actuators and sensors, may be integrated as component 1910A in mobile device 2500 as control button 2502, such as a volume control button, a power control button, or a camera shutter control button. The actuators and sensors may also or alternatively be incorporated into other components of the mobile device 2500. FIG. 25B is an illustration of an example mobile device incorporating a triboelectric-based sensor co-located on a substrate with a haptic feedback actuator in a display screen according to some embodiments of the disclosure. Mobile device 2500 may also include display screen 2504 with integrated array 1910A of actuators and sensors. Other types of mobile devices may also incorporate the actuators and sensors. FIG. 25C is an illustration of an example mobile device incorporating a triboelectric-based sensor co-located on a substrate with a haptic feedback actuator in a directional control pad according to some embodiments of the disclosure. Game controller 2510 may include directional pad 2512. Directional pad 2512 may include array 1910A of sensors 1912 and actuators 1914. Array 1910A may register swipes or directional movement of a finger on pad 2512 and translate the movement to the movement of a character or object in a video game. Game controller 2510 may also include control buttons 2514, which may be conventional buttons or buttons incorporating a pair or an array of sensors and actuators, similar to control button 2502 of FIG. 25A.

Thin film triboelectric-based sensors according to some embodiments may have a triboelectric layer based on a perfluoronated copolymer. The perfluoronated copolymer may be, for example, poly(methyl methacrylate)-co-poly(1H,1H-perfluoroctyl methacrylate). The perfluoronated copolymer may be manufactured by free radical polymerization in a solvent (e.g., benzene). In some embodiments, the perfluoronated copolymer may have a controlling perfluoro segment in proportion by weight of more than approximately fifty percent. Particular embodiments of synthesis for a triboelectric thin film are described below, but other copolymers, such as those described above, may be manufactured by different techniques. In one embodiment, the synthesis can be performed by refluxing benzene over a sodium/potassium alloy in the presence of benzophenone until the characteristic blue color of the benzophenone radical anion is present and then distilling the benzene.

Azobisisobutyronitrile (AIBN) can be recrystallized from methanol and dried in vacuum. Methyl methacrylate can be freshly distilled under a N₂ atmosphere prior to use. 1H,1H-perfluoroctyl methacrylate can be purified by passing through a basic alumina column and dried over Na₂SO₄ prior to use.

Referring to the reaction scheme below, synthesis of poly(methyl methacrylate)-co-poly(1H-1H-perfluorooctyl methacrylate) is described. The synthesis can begin with dry solvent (e.g., benzene 30 mL) in a reactor equipped with a nitrogen inlet and reflux condenser in subdued light. Nitrogen can be passed through the benzene to remove oxygen (e.g., for about 1.5 hours). Next, methyl methacrylate (1) (e.g., 1.0 g, 10 mmol) (1) and of 1H-1H-perfluorooctyl methacrylate (2) (e.g., 1.0 g 2.1 mmol) can be added, and the mixture stirred to dissolve the reagents. AIBN (e.g., 20 mg) can be then added, and the reaction mixture allowed to react at about 80 degrees Celsius while stirring for 12 hours. The resulting viscous solution can be precipitated by the addition a polar solvent (e.g., 250 ml of methanol). The isolated polymer can be further purified by two subsequent precipitations from chloroform into methanol, and the white polymer dried in vacuum. The resultant copolymer can have a molecular weight of between 5,000-50,000, or more particularly 8,700, and a DPI of 1.5-2.5, or more particularly 2.01, or at least, equal to, or between any two of 1.5, 1.75, 2.0, 2.1, 2.2., 2.3, 2.4, and 2.5.

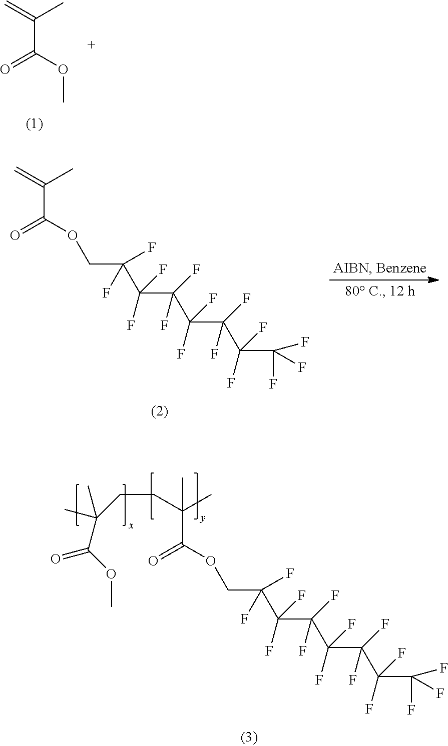

One example of a method for manufacturing a triboelectric sensor is now described, although other techniques and materials may be used in different embodiments of the invention. First, substrate preparation and cleaning is performed on a 100 nm PET substrate. After cleaning the substrate in an ultrasonic cleaner using acetone, isopropanol (IPA), and deionized water for about 5 minutes in each solvent, the substrate can be blow-dried with high purity nitrogen. Then, electrode deposition and patterning may be performed, such as by forming 50 nm Titanium/100 nm Gold electrodes with photolithography and electron beam evaporation. A 4 micrometer-thick AZ EC3027 positive photoresist (PR) is spin-coated on the substrate. The PR layer is then exposed with a broadband UV light source at a dose of 200 mJcm⁻² through a photomask to transfer the desired features. The PR is then developed using AZ 726 MIF developer. Ti/Au electrodes are then deposited using an electron beam evaporator without breaking vacuum. Lift-off using acetone is then performed to remove the unwanted areas and complete the patterning process. Then, triboelectric layer deposition is performed, which may include dissolving PVDF-TrFE copolymer (70/30 mol. %) in a solvent (e.g., dimethyl-formamide (DMF)) for 8 hours to provide a 20% by weight solution. Then, the solution is spin-coated on the PET film (with the electrodes on it) at a speed of 1000 rpm, forming a layer of about 12.2 um PVDF-TrFE. This process may be repeated 3 times to obtain a final thickness of around 36.6 um, or different number of times at different spin speeds to obtain other thicknesses. Each layer may be soft-baked in a hot plate at about 50 degrees Celsius for 10 minutes. After finishing the whole process, the film may be annealed in a conventional oven for about 4 hours at about 135 degrees Celsius under vacuum. Actual devices with a touch resolution of about 1 mm and 5 mm were fabricated, although different resolutions are possible. The devices are fabricated using a 100 um thick PET film as the flexible substrate, with 50 nm Titanium/100 nm Gold electrodes, and a 36.6 um thick PVDF-TrFE triboelectric active layer.

If implemented in firmware and/or software, the functions described above, such as with respect to the flow charts of FIG. 4 and FIG. 8, may be stored as one or more instructions or code on a computer-readable medium. Examples include non-transitory computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise random access memory (RAM), read-only memory (ROM), electrically erasable programmable read-only memory (EEPROM), compact-disc read-only memory (CD-ROM) or other optical disk storage, magnetic disk storage or other magnetic storage devices, or any other medium that can be used to store desired program code in the form of instructions or data structures and that can be accessed by a computer. Disk and disc includes compact discs (CD), laser discs, optical discs, digital versatile discs (DVD), floppy disks, and Blu-ray discs. Generally, disks reproduce data magnetically, and discs reproduce data optically. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

1. An apparatus, comprising:
a triboelectric-based component on a substrate; and
a haptic feedback component co-located on the same substrate and configured to operate in conjunction with the triboelectric-based component.

2. The apparatus of claim 1, further comprising processing circuitry coupled to the triboelectric-based component and to the haptic feedback component, wherein the processing logic is configured to perform steps comprising:
receiving an input signal from the triboelectric-based component; and
generating an output signal to activate the haptic feedback component.

3. The apparatus of claim 1, wherein the triboelectric-based component comprises:
a first electrode on the substrate; and
a first triboelectric thin film on the electrode.

4. The apparatus of claim 3, wherein the triboelectric-based component further comprises:
a spacer on the first triboelectric thin film;
a second triboelectric thin film on the spacer; and
a second electrode on the second triboelectric thin film,
wherein the first triboelectric thin film comprises an electronegative triboelectric material, and
wherein the second triboelectric thin film comprises an electropositive triboelectric material.

5. The apparatus of claim 1, wherein the triboelectric-based component and the haptic feedback component comprise a common active layer, wherein the common active layer comprises an electronegative triboelectric thin film.

6. The apparatus of claim 1, wherein the triboelectric-based component comprises a triboelectric thin film of at least one of polyvinylidene (PVDF), a PVDF copolymer, polydimethylsiloxane (PDMS), poly(methyl methacrylate) (PMMA), polytetrafluoroethylene, polymer foams, poly(methyl methacrylate)-co-poly(1H,1H-perfluoroctyl methacrylate), acetate, mica, nylon, an electronegative triboelectric layer, and an electropositive triboelectric layer.

7. The apparatus of claim 1, wherein the haptic feedback component comprises a piezoelectric-based component.

8. The apparatus of claim 7, wherein the piezoelectric-based component comprises a flexible piezoelectric-based component.

9. The apparatus of claim 7, wherein the piezoelectric-based component comprises a piezoelectric thin film of at least one of PVDF, a PVDF copolymer, poly(p-xylylene) polymer, cellular polypropylene, cellular polyethylene-naphthalate (PEN), voided charged polymers, polymer-based electrets, and piezoelectric composite materials having a polymeric matrix.

10. The apparatus of claim 1, wherein the triboelectric-based component and the haptic feedback component are coupled through a common electrode.

11. The apparatus of claim 1, wherein the haptic feedback component comprises a plurality of actuators.

12. The apparatus of claim 11, wherein the plurality of actuators comprise actuators of different sizes.

13. The apparatus of claim 11, wherein the haptic feedback component is configured to provide independent control of actuators of the plurality of actuators.

14. The apparatus of claim 11, wherein the plurality of actuators are co-located on the substrate such that the plurality of actuators at least partially surround the triboelectric-based component.

15. The apparatus of claim 2, wherein the processing circuitry comprises:
a read-out circuit coupled to the triboelectric-based component and configured to receive the input signal from the triboelectric-based component;
a signal processing circuit coupled to the read-out circuit and configured to determine a user input from the input signal; and
a drive circuit coupled to the read-out circuit and to the haptic feedback component and configured to generate the output signal for driving the haptic feedback component.

16. The apparatus of claim 15, wherein the drive circuit is configured to generate the output signal with at least one of a frequency, amplitude, sequence, and a duty cycle selected based, at least in part, on the input signal.

17. The apparatus of claim 2, wherein at least a portion of the processing circuitry is configured to receive power from the triboelectric-based component.

18. The apparatus of claim 1, wherein the triboelectric-based component has a square geometry, and wherein the haptic feedback component has a circular geometry.

19. The apparatus of claim 1, wherein at least a portion of the triboelectric-based component is vertically integrated with the haptic feedback component.

20. The apparatus of claim 1, wherein the haptic feedback component at least partially surrounds the triboelectric-based component.

21. The apparatus of claim 1, wherein the triboelectric-based component and the haptic feedback component are integrated into an array of force sensors comprising a plurality of triboelectric-based components and a plurality of haptic feedback components.

22. The apparatus of claim 21, further comprising a multiplexer coupled between the array of force sensors and the processing circuitry.

23. The apparatus of claim 21, wherein the array of force sensors has a ratio of haptic feedback components to triboelectric-based components being an integer greater than one, such that each triboelectric-based component is associated with two or more haptic feedback components.

24. The apparatus of claim 23, wherein the two or more haptic feedback components associated with each of the triboelectric-based components comprises haptic feedback components having different sizes.

25. The apparatus of claim 21, wherein the array of force sensors comprises a size of at least one square centimeter.

26. The apparatus of claim 21, wherein the array of force sensors is configured to provide touch resolution of between approximately 1 mm and approximately 15 mm.

27. The apparatus of claim 2, wherein the triboelectric-based component and the haptic feedback component are integrated into an array of force sensors comprising a plurality of triboelectric-based components and a plurality of haptic feedback components, and wherein the processing circuitry is configured to create a sensation for the user through the array of force sensors.

28. The apparatus of claim 27, wherein the plurality of haptic feedback components comprise actuators with different geometries and sizes, and wherein the different actuators can deliver different forces and thus resulting in different sensations to the user.

29. The apparatus of claim 27, wherein the processing circuitry comprises a haptic driver configured to drive the plurality of haptic feedback components with a plurality of haptic signals output to each feedback component of the plurality of feedback components.

30. The apparatus of claim 29, wherein the haptic driver circuit is configured to generate at least one of a step function, a sinusoidal function, and a pulse function.

31. The apparatus of claim 22, wherein the haptic driver circuit is configured to generate a haptic signal having a frequency of between approximately one hertz and approximately 100 kilohertz.

32. The apparatus of claim 29, wherein the haptic driver circuit is configured to individually address haptic feedback components within the plurality of haptic feedback components to localize haptic feedback.

33. The apparatus of claim 29, wherein the haptic driver circuit comprises:
a signal generator; and
a power amplifier coupled to the signal generator and coupled to the plurality of haptic feedback components, wherein the power amplifier is configured to drive the plurality of haptic feedback components with an output of the signal generator.

34. The apparatus of claim 1, wherein the substrate, the triboelectric-based component, and the haptic feedback component are at least partially transparent.

35. The apparatus of claim 1, wherein the substrate comprises a flexible substrate.

36. The apparatus of claim 1, wherein the apparatus comprises a switch for controlling a device.

37. The apparatus of claim 36, wherein the switch is configured to control a component of an automobile.

38. The apparatus of claim 37, wherein the switch is configured to control at least one of a window and an air conditioning of the automobile.

39. The apparatus of claim 36, wherein the switch is configured to control a lighting device.

40. A method of operating an electronic input device having a triboelectric-based component and a haptic feedback component co-located on a substrate, the method comprising:
receiving an input signal from the triboelectric-based component on the substrate; and
generating an output signal to actuate the haptic feedback component on the substrate.

41. The method of claim 40, wherein the step of generating the output signal comprises generating a signal with at least one of a frequency, amplitude, sequence, and duty cycle selected based, at least in part, on the received input signal, wherein the generated output signal is generated to drive a piezoelectric material of the haptic feedback component.

42. The method of claim 40, wherein the electronic input device comprises a plurality of haptic feedback components associated with the triboelectric-based component, and wherein the step of generating the output signal comprises controlling specific haptic feedback components of the plurality of haptic feedback components based, at least in part, on the received input signal.

43. The method of claim 42, wherein the step of generating the output signal comprises generating a localized haptic feedback event within the plurality of haptic feedback components.

44. The method of claim 40, wherein the step of receiving an input signal from the triboelectric-based component comprises receiving a plurality of input signals from a plurality of triboelectric-based components.

45. The method of claim 44, wherein the received input signal has a force sensor resolution of between approximately 1 mm and 15 mm.

46. An apparatus, comprising:
a user input device, comprising:
a triboelectric-based component on a substrate; and
a haptic feedback component co-located on the same substrate and configured to operate in conjunction with the triboelectric-based component,
wherein the user input device is configured to transmit user input received through the triboelectric-based component to an electronic device.

47. The apparatus of claim 46, wherein the user input device is configured to transmit the user input wirelessly through an antenna.

48. The apparatus of claim 47, wherein the user input device further comprises:
a read-out circuit coupled to the triboelectric-based component coupled to the antenna; and
a haptic controller coupled to the haptic feedback component coupled to the antenna.

49. The apparatus of claim 48, wherein the read-out circuit and the haptic controller are integrated in an integrated circuit (IC).

50. The apparatus of claim 49, wherein the integrated circuit (IC) is co-located on the same substrate as the triboelectric-based component and the haptic feedback component.

51. The apparatus of claim 48, wherein the haptic controller is configured to automatically generate feedback based, at least in part, on an indication received from the read-out circuit of user input received at the triboelectric-based component.

52. The apparatus of claim 48, wherein the haptic controller is configured to generate feedback based on a received instruction from the antenna.

53. The apparatus of claim 46, wherein the triboelectric-based component and the haptic feedback component comprise a common active layer, wherein the common active layer comprises an electronegative triboelectric thin film.

54. The apparatus of claim 46, wherein the triboelectric-based component comprises a triboelectric thin film of at least one of polyvinylidene (PVDF), a PVDF copolymer, polydimethylsiloxane (PDMS), poly(methyl methacrylate) (PMMA), polytetrafluoroethylene, polymer foams, poly(methyl methacrylate)-co-poly(1H,1H-perfluoroctyl methacrylate), acetate, mica, nylon, an electronegative triboelectric layer, and an electropositive triboelectric layer.

55. The apparatus of claim 46, wherein the haptic feedback component comprises a piezoelectric-based component.

56. The apparatus of claim 56, wherein the piezoelectric-based component comprises a piezoelectric thin film of at least one of PVDF, a PVDF copolymer, poly(p-xylylene) polymer, cellular polypropylene, cellular PEN, voided charged polymers, polymer-based electrets, and piezoelectric composite materials having a polymeric matrix.

57. The apparatus of claim 46, wherein the user input device further comprises a plurality of triboelectric-based components configured to receive the user input.

58. A wireless keyboard, comprising:
a plurality of keys, each key comprising:
a triboelectric-based component on a substrate; and
a haptic feedback component co-located on the same substrate and configured to operate in conjunction with the triboelectric-based component,
a wireless communications module coupled to the plurality of keys and configured to transmit user input received at the plurality of keys through the triboelectric-based component of each of the plurality of keys.

59. The wireless keyboard of claim 58, wherein the wireless keyboard further comprises:
a read-out circuit coupled to the plurality of keys and configured to receive input from the triboelectric-based component of each of the plurality of keys and further coupled to the wireless communications module and configured to provide the user input to the wireless communications module; and
a haptic controller coupled to the haptic feedback component.

60. The apparatus of claim 59, wherein the read-out circuit and the haptic controller and the wireless communications module are integrated in an integrated circuit (IC).

61. The apparatus of claim 60, wherein the integrated circuit (IC) is co-located on the same substrate as the triboelectric-based component and the haptic feedback component.

62. The apparatus of claim 59, wherein the haptic controller is configured to automatically generate feedback based, at least in part, on an indication received from the read-out circuit of user input received at the triboelectric-based component, wherein the generated feedback simulates a mechanical depression of a key.

63. The wireless keyboard of claim 58, wherein the triboelectric-based component and the haptic feedback component comprise a common active layer, wherein the common active layer comprises an electronegative triboelectric thin film.

64. The wireless keyboard of claim 58, wherein the triboelectric-based component comprises a triboelectric thin film of at least one of polyvinylidene (PVDF), a PVDF copolymer, polydimethylsiloxane (PDMS), poly(methyl methacrylate) (PMMA), polytetrafluoroethylene, polymer foams, poly(methyl methacrylate)-co-poly(1H,1H-perfluoroctyl methacrylate), acetate, mica, nylon, an electronegative triboelectric layer, and an electropositive triboelectric layer.

65. The wireless keyboard of claim 58, wherein the haptic feedback component comprises a piezoelectric-based component.

66. The wireless keyboard of claim 65, wherein the piezoelectric-based component comprises a piezoelectric thin film of at least one of PVDF, a PVDF copolymer, Parylene-C, cellular polypropylene, cellular PEN, voided charged polymers, polymer-based electrets, and piezoelectric composite materials having a polymeric matrix.

67. The wireless keyboard of claim 58, wherein the user input device further comprises a plurality of triboelectric-based components configured to receive the user input.
